(19) United States
(12) Patent Application Publication
(10) Pub. No.: US 2009/0115927 A1
(43) Pub. Date: May 7, 2009

(54) DISPLAY MODULE WITH A REPLACEABLE COVER AND ELECTRONIC DEVICE HAVING THE SAME

(75) Inventor: Hui-Liang Chang, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: COMPAL ELECTRONICS, INC., Taipei City (TW)

(21) Appl. No.: 12/121,796

(22) Filed: May 16, 2008

Related U.S. Application Data
(60) Provisional application No. 60/984,378, filed on Nov. 1, 2007.

(51) Int. Cl. H05K 5/00; G02F 1/1333

(52) U.S. Cl. 349/58; 361/679.27

(57) ABSTRACT

A display module including a display panel, a bezel, a cover, a flexible film, and a plurality of signal transmission wires is provided. The display panel has a display region. The bezel has an opening. The cover is assembled with the bezel. The display panel is disposed between the bezel and the cover, and the display region of the display panel is exposed from the opening of the bezel. The flexible film is disposed between the display panel and the cover. The signal transmission wires are disposed on the flexible film.

### CROSS-REFERENCE TO RELATED APPLICATION

This application claims the priority benefit of U.S.A. provisional application Ser. No. 60984378, filed on Nov. 1, 2007. The entirety of the above-mentioned patent application is hereby incorporated by reference herein and made a part of specification.

### BACKGROUND OF THE INVENTION

1. Field of the Invention

The present invention generally relates to a display module with a replaceable cover and an electronic device having the same, and more particularly, to a display module with a flexible film for wire arrangement and an electronic device having the same.

2. Description of Related Art

After black-and-white TV sets in the work mode of cathode ray tubes (CRT) were developed, image display technology has been continuously progressing rapidly. However, displays in the work mode of cathode ray tubes have disadvantages such as huge volume, heavy weight, and high radiation, so new flat panel display techniques have been continuously developed. Among the flat panel display technologies, a liquid crystal display (LCD) technology having advantages of being light, thin, short and small, power saving, radiation-free, full color, and portable is the most mature and translators, digital cameras, digital video cameras, personal digital assistants (PDA), notebook computers, and even the large electronic devices such as desktop displays and TV sets have employed the liquid crystal displays.

A conventional notebook computer has a mainframe and a display module pivoted on a longer side of the mainframe. The display module comprises a cover, a LCD panel, a pair of bracket, and a bezel. The LCD panel is fastened to the cover by the brackets, and the bezel is fastened to the cover for covering the border of the LCD panel. The notebook computer further comprises a plurality of signal transmission wires arranged between the cover and the LCD module so as to electrically connect the LCD panel and a motherboard of the mainframe.

In addition, the notebook computer may have some expansion devices such as a web camera, an antenna, and so on according to user's requirement. The expansion devices are also mounted on the inner surface of the cover. Similarly, signal transmission wires for electrically connecting the expansion devices and the motherboard of the mainframe are also arranged between the cover and the LCD module.

In a conventional assembling process of the display module, the cover must be provided at first, and then the signal transmission wires and the expansion devices are directly disposed on the inner surface of the cover via adhesive or other means. After that, the LCD panel is mounted on the inner surface of the cover via the bracket. Finally, the bezel is latched to the cover for covering the border of the LCD panel.

However, it is hard to replace the cover by a user or in a service station since the signal transmission wires and the expansion devices are already disposed on the inner surface of the cover. Furthermore, the appearance of the cover may be damaged since the cover must be provided in the beginning of the conventional assembling process.

### SUMMARY OF THE INVENTION

Accordingly, the present invention is directed to a display module with a replaceable cover and an electronic device having the same. The present invention is to dispose a flexible film in the display module, such that the signal transmission wires and the expansion devices are disposed on the flexible film instead of the cover. Therefore, the assembling process of the display module of the present invention is easier compared with that of the conventional display module.

The present invention is directed to a display module with a replaceable cover of an electronic device. The display module comprises a display panel, a bezel, a cover, a flexible film, and a plurality of signal transmission wires. The display panel has a display region. The bezel has an opening. The cover is assembled with the bezel. The display panel is disposed between the bezel and the cover, and the display region of the display panel is exposed from the opening of the bezel. The flexible film is disposed between the display panel and the cover. The signal transmission wires are disposed on the flexible film.

According to an embodiment of the present invention, the display module further comprises a bracket disposed on the periphery of the display panel. Furthermore, the display panel is fastened to the bezel by the bracket.

According to an embodiment of the present invention, the bezel further comprises a first sliding connection portion, and the cover comprises a second sliding connection portion. The cover is fastened to the bezel through the second sliding connection portion slidingly connected to the first sliding connection portion.

According to an embodiment of the present invention, the display panel is a liquid crystal display panel.

According to an embodiment of the present invention, the flexible film has at least one opening through which one of the signal transmission wires passes.

According to an embodiment of the present invention, a material of the flexible film comprises polymer.

According to an embodiment of the present invention, the signal transmission wires are electrically connected to a mainframe of the electronic device.

The present invention is also directed to a flexible film suitable for being disposed within a display module of an electronic device. The display module comprises a bezel, a cover assembled with the bezel, a display panel disposed between the bezel and the cover, and a plurality of signal transmission wires. The flexible film is characterized in that the flexible film is disposed between the display panel and the cover, and the signal transmission wires are disposed thereon.

According to an embodiment of the present invention, the flexible film has at least one opening through which one of the signal transmission wires passes.

According to an embodiment of the present invention, a material of the flexible film comprises polymer.

According to an embodiment of the present invention, the signal transmission wires are electrically connected to a mainframe of the electronic device.

The present invention is to dispose a flexible film in the display module, such that the signal transmission wires and the expansion devices are disposed on the flexible film instead of the cover. By using the arrangement of the flexible film, the difficulty in assembling present in the prior art due to the disposition of the signal transmission wires between the cover and the display panel can be effectively avoided, and thus the assembling time of the display module is also reduced.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a three-dimensional diagram showing an electronic device according to an embodiment of the present invention.

FIG. 2A is a three-dimensional exploded diagram showing the display module of the electronic device as shown in FIG. 1.

FIG. 2B is a three-dimensional diagram showing the assembled display module as shown in FIG. 2A.

FIG. 3 is a three-dimensional diagram showing the first sliding connection portion of the bezel and the second sliding connection portion of the cover according to an embodiment of the present invention.

FIGS. 4A and 4B are schematic diagrams showing the first sliding connection portion and the second sliding connection portion before and after assembly.

FIG. 5 is a three-dimensional exploded diagram showing the flexible film and the signal transmission wires disposed thereon.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

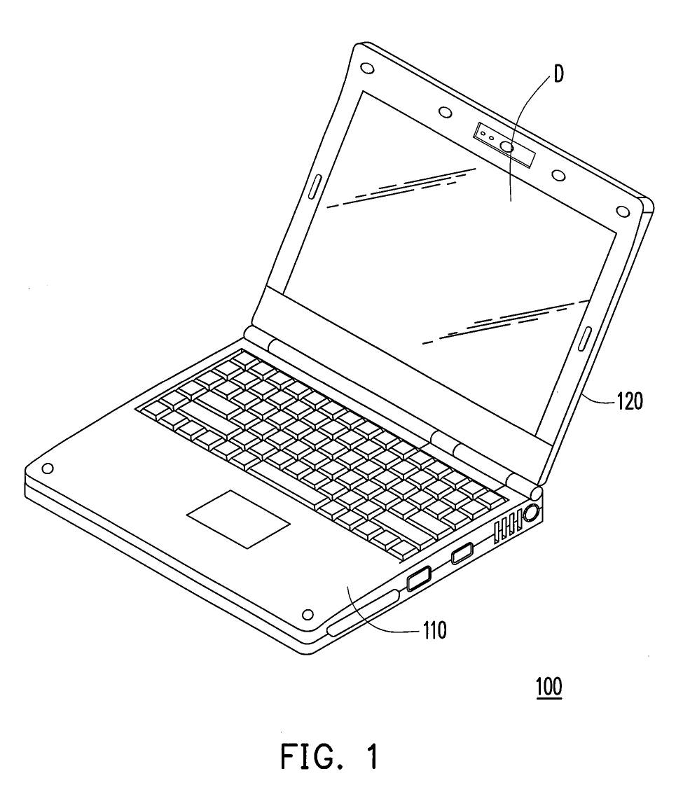

FIG. 1 is a three-dimensional diagram showing an electronic device according to an embodiment of the present invention. In this embodiment, a notebook computer is taken as an example for illustration. Referring to FIG. 1, the electronic device 100 of the present embodiment comprises a mainframe 110 and a display module 120 pivoted on the mainframe 110. The mainframe 110 is used for processing electronic data in the electronic device 100. The display module 120 pivotally connected to the mainframe 110 is used for displaying the output of the electronic data processing of the mainframe 110, so that the users can know the results of the executions of the application programs or the function options from the display module 120. The display module 120 is described in detail in the following.

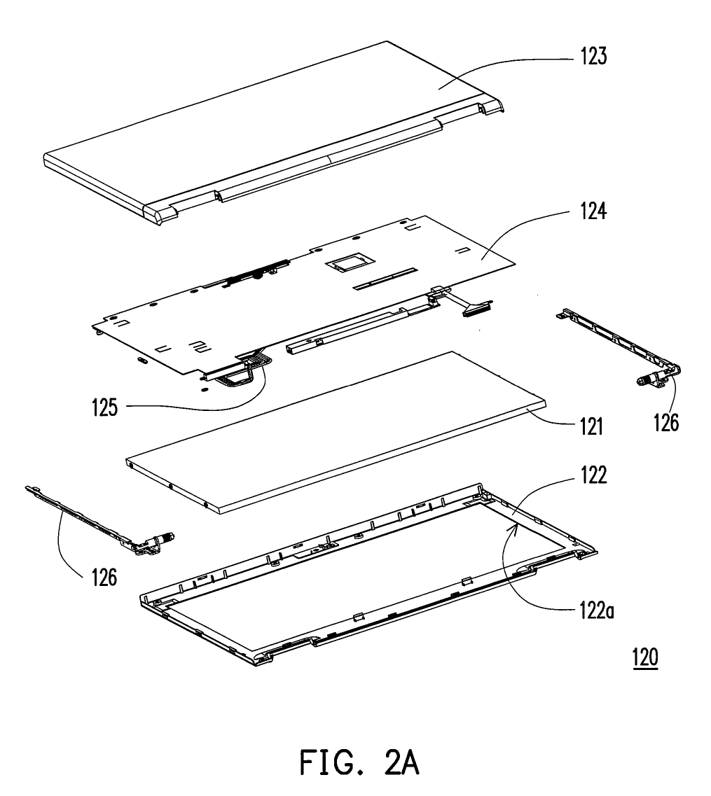

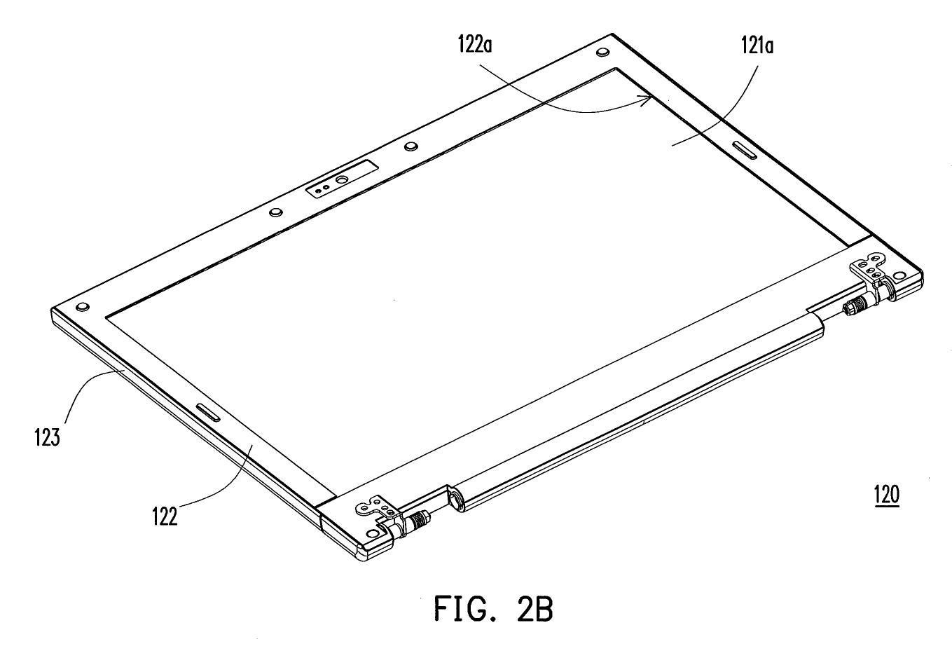

FIG. 2A is a three-dimensional exploded diagram showing the display module of the electronic device as shown in FIG. 1. FIG. 2B is a three-dimensional diagram showing the assembled display module as shown in FIG. 2A. Referring to FIGS. 2A and 2B, the display module 120 comprises a display panel 121, a bezel 122, a cover 123, a flexible film 124, and a plurality of signal transmission wires 125. Generally speaking, the display panel 121 is a LCD panel and has a display region 121a labelled in FIG. 2B. The bezel 122 has an opening 122a, such that the display region 121a of the display panel 121 is exposed from the opening 122a of the bezel 122.

The cover 123 is assembled with the bezel 122, and a receiving space is formed between the cover 123 and the bezel 122 for receiving the display panel 121. In one embodiment of the present invention, the bezel 122 further comprises a first sliding connection portion, and the cover 123 comprises a second sliding connection portion corresponding to the first sliding connection portion. The cover 123 is fastened to the bezel 122 through the second sliding connection portion slidingly connected to the first sliding connection portion. The display panel 121 is disposed between the bezel 122 and the cover 123, and the display region 121a of the display panel 121 is exposed from the opening 122a of the bezel 122.

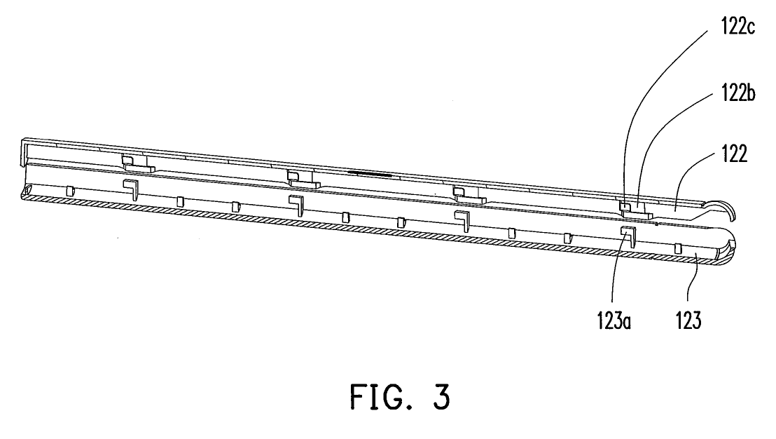

FIG. 3 is a three-dimensional diagram showing the first sliding connection portion of the bezel and the second sliding connection portion of the cover according to an embodiment of the present invention. In this diagram, only a part of the bezel and the cover are shown for the convenience of illustration. Referring to FIG. 3, in this embodiment, the first sliding connection portion comprises an opening 122b and a baffle 122c next to the opening 122b, and the second sliding connection portion comprises a protrusion 123a corresponding to the opening 122b and the baffle 122c.

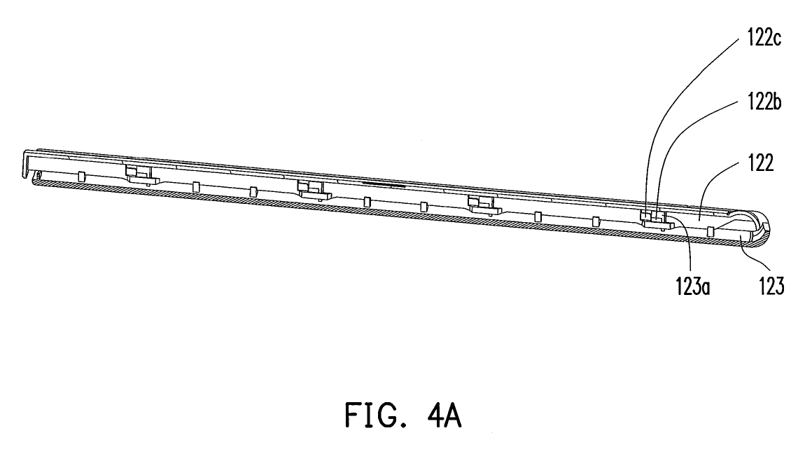

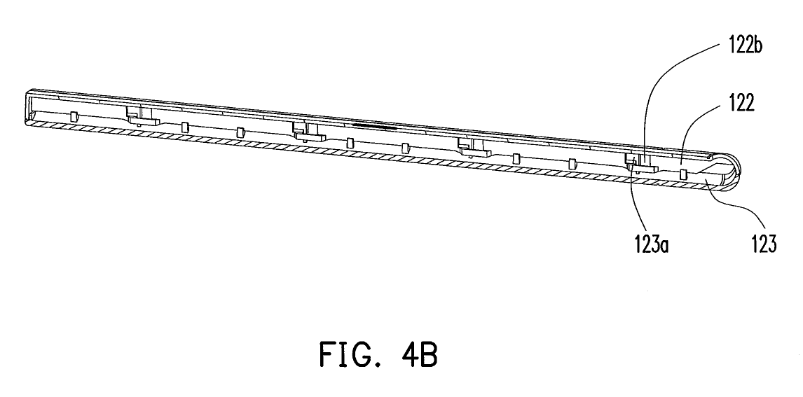

FIGS. 4A and 4B are schematic diagrams showing the first sliding connection portion and the second sliding connection portion before and after assembly. Referring to FIG. 4A, the protrusions 123a of the cover 123 are placed within the openings 122b of the bezel 122, respectively. Then, referring to FIG. 4B, the cover 123 is pushed to make the protrusions 123a lean against the corresponding baffles 122c, such that the cover 123 is fastened onto the bezel 122 through the combination of the first sliding connection portion and the second sliding connection portion. The structures of the first sliding connection portion and the second sliding connection portion are not limited in the present embodiment.

Referring to FIGS. 2A and 2B again, the present embodiment is to dispose the flexible film 124 between the display panel 121 and the cover 123, such that the signal transmission wires 125 are disposed on the flexible film 124 for wire arrangement. In one embodiment of the present invention, the signal transmission wires 125 are electrically connected to the mainframe 110 of the electronic device 100. Thus, the difficulty in assembling present in the prior art due to the disposition of the signal transmission wires between the cover and the display panel can be effectively avoided. Besides, the display module 120 may further comprise a bracket 126 disposed on the periphery of the display panel 121, and the display panel 121 is fastened to the bezel 122 by the bracket 126.

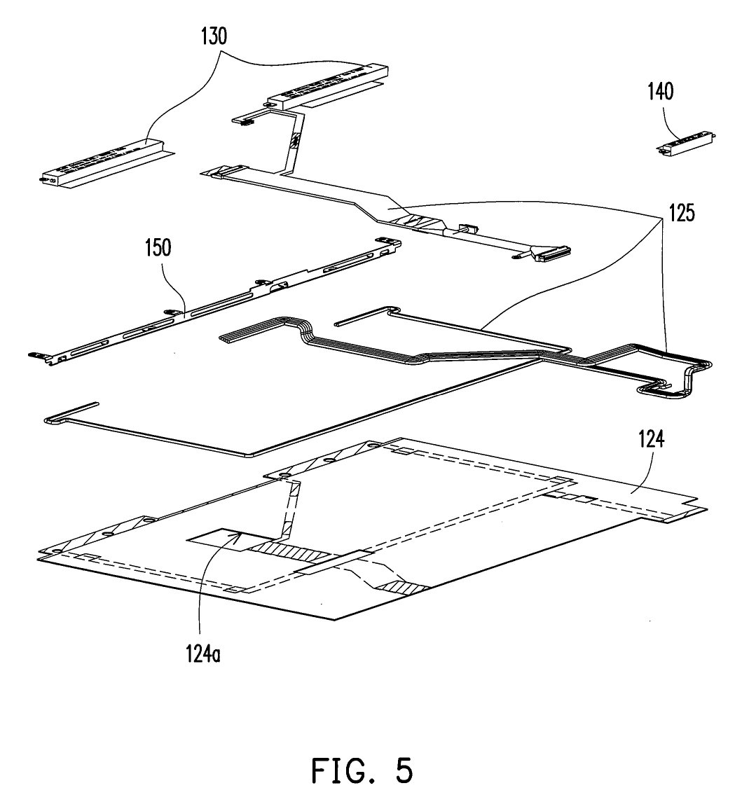

FIG. 5 is a three-dimensional exploded diagram showing the flexible film and the signal transmission wires disposed thereon. Referring to FIG. 5, the flexible film 124 may have an opening 124a, such that one or more of the signal transmission wires 125 may pass through the opening 124a. The material of the flexible film 124 comprises polymer or other suitable material for reducing electromagnetic interference (EMI). Furthermore, the electronic device 100 may have some expansion devices such as an antenna 130 fixed on a bracket 150, a web camera 140 and the like mounted on the flexible film 124.

The process of assembling the LCD module 120 is described in the following. First, the LCD panel 121 is fastened to the bezel 122 through the bracket 126, to make the LCD panel 121, the bracket 126 and the bezel 122 assembled as a unit. Then, the flexible film 124 having the signal transmission wires 125 and expansion devices disposed thereon is placed on the LCD panel 121. Finally, the cover 123 is fastened to the bezel 122 for fixing the LCD panel 121 and the flexible film 124.

between the cover 123 and the bezel 122. Thus, the assembling process of the LCD module 120 according to the present invention is easier, and the problem of damaging the appearance of the cover 123 may be resolved, too.

In summary, the present invention is to dispose a flexible film in the display module, such that the signal transmission wires and the expansion devices are disposed on the flexible film instead of the cover. By using the arrangement of the flexible film, the difficulty in assembling present in the prior art due to the disposition of the signal transmission wires between the cover and the display panel can be effectively avoided, and thus the assembling time of the display module is also reduced. Besides, the cover is provided later during the assembling process, and accordingly the appearance of the cover may be protected from being scratched or damaged. In addition, the signal transmission wires and the expansion devices are disposed on the flexible film, and therefore it is easier to replace the cover by a user or in a service station.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A display module with a replaceable cover of an electronic device, the display module comprising:
a display panel;
a bezel;
a cover, assembled with the bezel, wherein the display panel is disposed between the bezel and the cover;
a flexible film, disposed between the display panel and the cover; and
a plurality of signal transmission wires, disposed between the flexible film and the display panel;
the signal transmission wires, disposed on the flexible film.

2. The display module according to claim 1, wherein the display panel has a display region, and the bezel has an opening for exposing the display region of the display panel.

3. The display module according to claim 1, further comprising a bracket disposed on the periphery of the display panel, wherein the display panel is fastened to the bezel by the bracket.

4. The display module according to claim 1, wherein the bezel further comprises a first sliding connection portion, and the cover comprises a second sliding connection portion, and the cover is fastened to the bezel through the second sliding connection portion slidingly connected to the first sliding connection portion.

5. The display module according to claim 1, wherein the display panel is a liquid crystal display panel.

6. The display module according to claim 1, wherein the flexible film has at least one opening through which one of the signal transmission wires passes.

7. The display module according to claim 1, wherein a material of the flexible film comprises a material for reducing electromagnetic interference.

8. The display module according to claim 1, wherein the signal transmission wires are electrically connected to a mainframe of the electronic device.

9. A flexible film, suitable for being disposed within a display module of an electronic device, the display module comprising a bezel, a cover assembled with the bezel, a display panel disposed between the bezel and the cover, and a plurality of signal transmission wires, wherein the flexible film is characterized in that the flexible film is disposed between the display panel and the cover, and the signal transmission wires between the display panel and the cover are disposed thereon.

10. The flexible film according to claim 9, wherein the flexible film has at least one opening through which one of the signal transmission wires passes.

11. The flexible film according to claim 9, wherein a material of the flexible film comprises a material for reducing electromagnetic interference.

12. The flexible film according to claim 9, wherein the signal transmission wires are electrically connected to a mainframe of the electronic device.

13. The display module according to claim 1, wherein the flexible film approximately covers the display panel.

14. The flexible film according to claim 9, wherein the flexible film approximately covers the display panel.
